(19) United States
(12) Patent Application Publication
(10) Pub. No.: US 2026/0164870 A1
(43) Pub. Date: Jun. 11, 2026

(54) DISPLAY DEVICE

(71) Applicant: LG Display Co., Ltd., Seoul (KR)

(72) Inventors: HoJin RYU, Goyang-si (KR); Jaemin PARK, Ansan-si (KR)

(73) Assignee: LG Display Co., Ltd., Seoul (KR)

(21) Appl. No.: 19/297,469

(22) Filed: Aug. 12, 2025

(30) Foreign Application Priority Data
Nov. 26, 2024 (KR) 10-2024-0171310

(51) Int. Cl. H10H 20/857; H10H 20/01; H10H 20/832; H10H 20/841; H10H 29/01; H10H 29/49

(52) U.S. Cl. CPC H10H 20/857; H10H 20/034; H10H 20/0364; H10H 20/835; H10H 20/841; H10H 29/034; H10H 29/49

(57) ABSTRACT

A display device according to one or more examples includes transistors disposed on the substrate, reflection electrodes disposed on the transistors, bonding layers which are bonded to some of the reflection electrodes and include a conductive black material, light emitting diodes which are disposed on the bonding layers so as to correspond to the bonding layers and include a first electrode, a first semiconductor layer, an active layer, a second semiconductor layer, and a second electrode, and reflection layers which are disposed on the bonding layers, are electrically connected to the reflection electrodes, respectively, and are in contact with the light emitting diodes. Accordingly, light emitted from the light emitting diode is suppressed from being absorbed by the bonding layer, and a light extraction efficiency may be improved.

### CROSS-REFERENCE TO RELATED APPLICATIONS

This application claims the benefit of and priority to Korean Patent Application No. 10-2024-0171310 filed on Nov. 26, 2024, in the Korean Intellectual Property Office, the entire contents of which are incorporated herein by reference for all purposes.

### BACKGROUND

### 1. Technical Field

The present disclosure relates to a display device, and more particularly, for example, without limitation, to a display device in which a bonding layer including a conductive black material is disposed.

### 2. Description of Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance may be displayed.

The description of related art should not be considered prior art merely because it is mentioned in or associated with this section. The description of related art includes information that describes one or more aspects of the subject technology, and the description in this section does not limit the scope of the invention.

### SUMMARY

An aspect to be achieved by the present disclosure is to provide a display device in which a bonding layer corresponding to a light emitting diode has a reduced size.

Another aspect to be achieved by the present disclosure is to provide a display device which suppresses light emitted from a light emitting diode from being absorbed by a bonding layer.

Still another aspect to be achieved by the present disclosure is to provide a display device which reflects upwardly light which is emitted from a light emitting diode to be directed to a lower portion of the light emitting diode to improve a light extraction efficiency.

Aspects of the present disclosure are not limited to the above-mentioned aspects, and other aspects, which are not mentioned above, can be clearly understood by those skilled in the art from the following descriptions.

A display device according to one aspect of the present disclosure comprises a substrate, a plurality of sub pixels, a plurality of transistors disposed on the substrate, a plurality of reflection electrodes disposed on the plurality of transistors, a plurality of bonding layers which is bonded to some of the plurality of reflection electrodes and includes a conductive black material, a plurality of light emitting diodes which is disposed on the plurality of bonding layers so as to correspond to the plurality of bonding layers and includes a first electrode, a first semiconductor layer, an active layer, a second semiconductor layer, and a second electrode, and a plurality of reflection layers which is disposed on the plurality of bonding layers, is electrically connected to the plurality of reflection electrodes, respectively, and is in contact with the plurality of light emitting diodes. Accordingly, light emitted from the light emitting diode is suppressed from being absorbed by the bonding layer and a light extraction efficiency may be improved.

A display device according to another aspect of the present disclosure comprises a substrate, a transistor disposed on the substrate, a power line disposed on the substrate, a first reflection electrode which is disposed on the transistor and is electrically connected to the transistor, a second reflection electrode which is disposed on the power line and is electrically connected to the power line, a bonding layer which is electrically connected to one of the first reflection electrode and the second reflection electrode and includes a conductive black material, a light emitting diode disposed on the bonding layer, and a reflection layer which is disposed so as to cover the bonding layer. Accordingly, light directed to the lower portion of the light emitting diode is upwardly reflected so that a luminous efficiency may be improved.

Other detailed matters of the example embodiments are included in the detailed description and the drawings.

According to one or more aspects of the present disclosure, in the display device, a size of a bonding layer corresponding to each of light emitting diodes with a reduced size may be further reduced.

According to one or more aspects of the present disclosure, the display device suppresses light emitted from the light emitting diode from being absorbed by the bonding layer to improve the luminous efficiency.

According to one or more aspects of the present disclosure, the display device upwardly reflects light which is emitted from the light emitting diode to be directed to the lower portion of the light emitting diode to improve the light extraction efficiency so that the display device may be driven with a low power.

The effects according to one or more aspects of the present disclosure are not limited to the contents exemplified above, and more various effects are included in the present disclosure.

The aspects to be achieved by the present disclosure, the means for achieving the aspects, and the effects of the present disclosure described above do not specify essential features of the claims, and, thus, the scope of the claims is not limited to the disclosure of the present disclosure.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a schematic diagram of a display device according to an example embodiment of the present disclosure;

FIG. 2 is a plan view of a pixel of a display device according to an example embodiment of the present disclosure;

FIG. 3 is a cross-sectional view taken along a line A-A′ of FIG. 2;

FIGS. 4A to 4G are process diagrams for explaining a manufacturing method of a pixel of a display device according to an example embodiment of the present disclosure; and

FIG. 5 is a cross-sectional view of a sub pixel of a display device according to another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

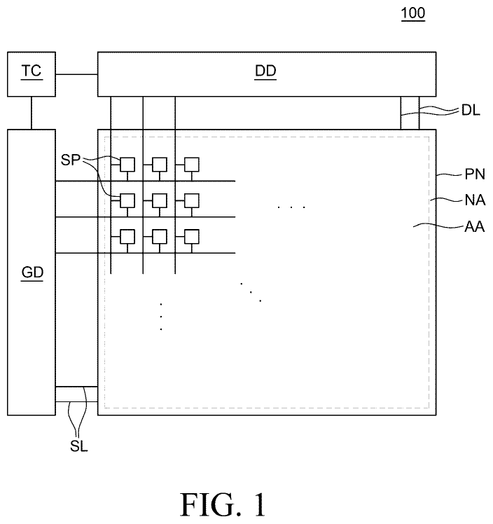

FIG. 1 is a schematic diagram of a display device according to an example embodiment of the present disclosure.

In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line VDD, a low potential power line VSS, a reference line, and the like.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. A sub pixel SP is a minimum unit which configures the active area AA and n sub pixels SP form one pixel PX. For example, n may be 3 or 4. In each of the plurality of sub pixels SP, a light emitting diode and a thin film transistor for driving the light emitting diode may be disposed. The plurality of light emitting diodes may be defined in different manners depending on the type of the display panel PN. For example, when the display panel PN is an inorganic light emitting display panel PN, the light emitting diode may be a light emitting diode (LED) or a micro light emitting diode (LED).

In the active area AA, a plurality of signal lines which transmits various signals to the plurality of sub pixels SP is disposed. For example, the plurality of signal lines includes a plurality of data lines DL which supplies a data voltage to each of the plurality of sub pixels SP and a plurality of scan lines SL which supplies a gate voltage to each of the plurality of sub pixels SP. The plurality of scan lines SL extends along one direction in the active area AA to be connected to the plurality of sub pixels SP and the plurality of data lines DL extends along a direction different from the one direction in the active area AA to be connected to the plurality of sub pixels SP. In addition, in the active area AA, a low potential power line VSS and a high potential power line VDD may be further disposed, but the present disclosure is not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board and may be electrically connected to the display panel PN by bonding the flexible film and the printed circuit board to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area of the non-active area NA to dispose the gate driver GD and the pad electrode needs to be ensured. By doing this, however, a bezel will be increased.

In contrast, when the gate driver GD is mounted in the active area AA in the GIA manner and a side line which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel with substantially no bezel may be implemented.

The plurality of sub pixels SP may form one pixel. Further, the plurality of sub pixels SP may include sub pixels SP for emitting different color light. For example, the plurality of sub pixels SP may include a red sub pixel, a green sub pixel, and a blue sub pixel. However, the present disclosure is not limited thereto and the plurality of sub pixels SP may further include a sub pixel SP which emits different color light.

At least some of the plurality of sub pixels SP may include two light emitting diodes. At this time, two light emitting diodes may emit same color light. For example, in the red sub pixel, two light emitting diodes which emit red light may be disposed, in the green sub pixel, two light emitting diodes which emit green light may be disposed, and in the blue sub pixel, two light emitting diodes which emit blue light may be disposed.

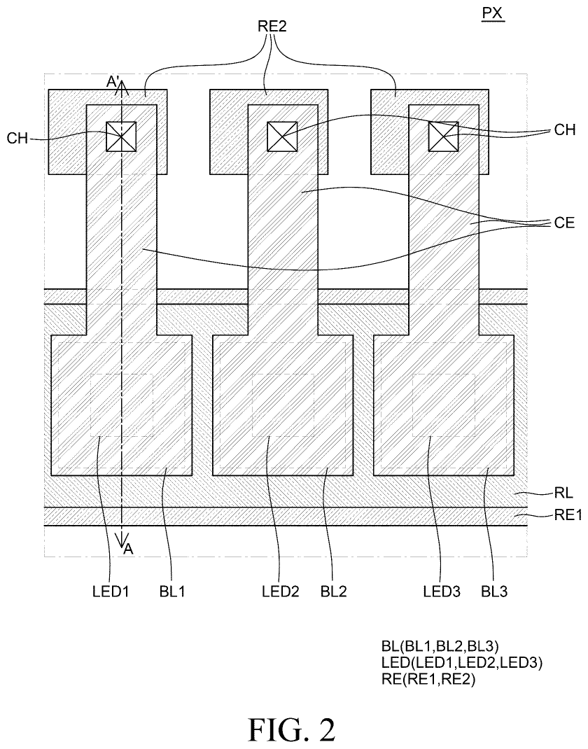

FIG. 2 is a plan view of a pixel of a display device according to an example embodiment of the present disclosure. For example, FIG. 2 is an enlarged plan view of a part of a pixel PX of the display device 100 according to an example embodiment of the present disclosure.

Referring to FIG. 2, the pixel PX of the display device 100 according to the example embodiment of the present disclosure may include a first light emitting diode LED1, a second light emitting diode LED2, and a third light emitting diode LED3. The first light emitting diode LED1, the second light emitting diode LED2, and the third light emitting diode LED3 may emit different color light. For example, the first light emitting diode LED1 emits red light and may be disposed in a red sub pixel. The second light emitting diode LED2 emits green light and may be disposed in a green sub pixel. The third light emitting diode LED3 emits blue light and may be disposed in a blue sub pixel.

The first light emitting diode LED1, the second light emitting diode LED2, and the third light emitting diode LED3 may be disposed in the same row. Further, the first light emitting diode LED1, the second light emitting diode LED2, and the third light emitting diode LED3 are disposed to be spaced apart from each other with the same interval, but the present disclosure is not limited thereto. For example, the first light emitting diodes LED1, the second light emitting diodes LED2, and the third light emitting diodes LED3 may be disposed to be spaced apart from each other with different intervals.

A plurality of bonding layers BL may be disposed below the first light emitting diode LED1, the second light emitting diode LED2, and the third light emitting diode LED3. The plurality of bonding layers BL may be disposed so as to correspond to the first light emitting diode LED1, the second light emitting diode LED2, and the third light emitting diode LED3, respectively. For example, the plurality of bonding layers may include a first bonding layer BL1 disposed below the first light emitting diode LED1, a second bonding layer BL2 disposed below the second light emitting diode LED2, and a third bonding layer BL3 disposed below the third light emitting diode LED3.

An area of each of the plurality of bonding layers BL may be larger than an area of a respective one of the plurality of light emitting diodes LED. Therefore, each of the plurality of light emitting diodes LED may completely overlap a respective one of the plurality of bonding layers BL. For example, on the plane, each of the plurality of light emitting diodes LED may be disposed inside a respective one of the plurality of bonding layers BL so as not to be deviated from the respective one of the plurality of bonding layers BL. A planar shape of each of the plurality of bonding layers BL may correspond to a planar shape of a respective one of the plurality of light emitting diodes LED, but the present disclosure is not limited thereto.

The plurality of bonding layers BL may be disposed on the same row and is spaced apart from each other. For example, the plurality of bonding layers BL may be spaced apart from each other with the same interval, but the present disclosure is not limited thereto. As another example, the plurality of bonding layers BL may be spaced apart from each other with different intervals.

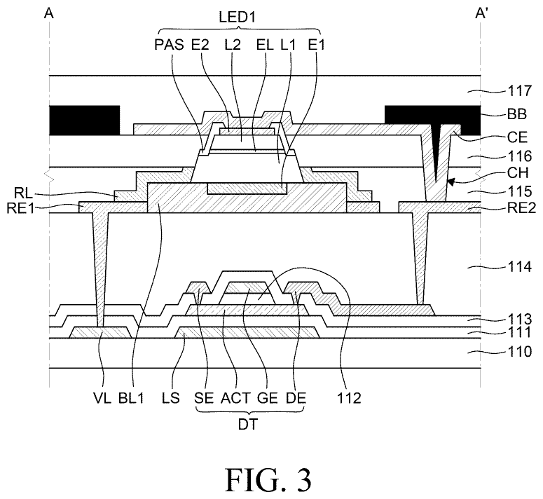

The plurality of reflection layers RL is disposed in the vicinity of the plurality of bonding layers BL. At this time, the plurality of reflection layers RL may be disposed so as to enclose the plurality of bonding layers BL. Specifically, on the plane, the plurality of reflection layers RL may be disposed so as to enclose entire side surfaces of the plurality of bonding layers BL. Further, the plurality of reflection layers RL may be disposed so as to overlap at least a part of top surfaces of the plurality of bonding layers BL. Therefore, the plurality of reflection layers RL is in contact with the plurality of light emitting diodes LED. Accordingly, the plurality of reflection layers RL may cover fully an area of the top surfaces of the plurality of bonding layers BL which does not overlap the plurality of light emitting diodes LED, which will be described in more detail with reference to FIG. 3.

The plurality of reflection layers RL may also be disposed in an area between the plurality of bonding layers BL which is spaced apart from each other. Therefore, the plurality of bonding layers BL may be electrically connected through the plurality of reflection layers RL. Further, on the plane, the plurality of bonding layers BL and the plurality of light emitting diodes LED may be disposed inside the plurality of reflection layers RL. A plurality of reflection electrodes RE is disposed in the vicinity of the plurality of bonding layers BL. The plurality of reflection electrodes RE may include a first reflection electrode RE1 which is disposed so as to enclose the plurality of bonding layers BL and a second reflection electrode RE2 which is spaced apart from the first reflection electrode RE1.

The first reflection electrode RE1 may be disposed below the plurality of reflection layers RL. Further, the first reflection electrode RE1 may be in contact with the plurality of reflection layers RL. Therefore, the first reflection electrode RE1 and the plurality of reflection layers RL may be electrically connected.

An area of the first reflection electrode RE1 on the plane may be larger than an area of the plurality of reflection layers RL. Further, the first reflection electrode RE1 and the plurality of reflection layers RL may completely overlap. For example, the plurality of reflection layers RL may be disposed on the first reflection electrode RE1 so as not to be deviated from the first reflection electrode RE1, but the present disclosure is not limited thereto. For example, ends of the plurality of reflection layers RL may be disposed on the first reflection electrode RE1.

The first reflection electrode RE1 may be disposed so as to enclose the plurality of bonding layers BL. Further, the first reflection electrode RE1 may be in contact with the plurality of bonding layers BL. Therefore, the plurality of bonding layers BL may be electrically connected to the first reflection electrode RE1. Further, the plurality of bonding layers BL may be electrically connected to each other through the first reflection electrode RE1.

The second reflection electrode RE2 may be spaced apart from the first reflection electrode RE1. Further, a plurality of second reflection electrodes RE2 is provided and is spaced apart from each other. For example, the plurality of second reflection electrodes RE2 may be spaced apart from each other in the same row.

The plurality of second reflection electrodes RE2 may be electrically connected to the plurality of light emitting diodes LED. Therefore, the number of the plurality of second reflection electrodes RE2 may be the same as the number of the plurality of light emitting diodes LED, but the present disclosure is not limited thereto. The plurality of second reflection electrodes RE2 may be disposed to correspond to the plurality of light emitting diodes LED, respectively, on the same column, but the present disclosure is not limited thereto.

A connection electrode CE may be disposed on one of the plurality of second reflection electrodes RE2 and a respective one of the plurality of light emitting diodes LED. The connection electrode CE may electrically connect one of the plurality of light emitting diodes LED and a respective one of the plurality of second reflection electrodes RE2. Therefore, a plurality of connection electrodes CE may be provided. For example, one second reflection electrode RE2 and the first light emitting diode LED1 may be electrically connected through one connection electrode CE. Further, another second reflection electrode RE2 and the second light emitting diode LED2 may be electrically connected through another connection electrode CE. Specifically, one end of one of the plurality of connection electrodes CE is connected to a respective one of the plurality of light emitting diodes LED and the other end of the one of the plurality of connection electrodes CE may be connected to a respective one of the plurality of second reflection electrodes RE2 through a contact hole CH.

Hereinafter, a cross-sectional structure of one sub pixel SP of the display device 100 according to the example embodiment of the present disclosure will be described in detail with reference to FIG. 3.

FIG. 3 is a cross-sectional view taken along a line A-A′ of FIG. 2. Specifically, FIG. 3 is a cross-sectional view of one sub pixel SP of a display device 100 according to an example embodiment of the present disclosure.

Referring to FIG. 3, the display device 100 according to the example embodiment of the present disclosure includes a substrate 110, a buffer layer 111, a gate insulating layer 112, an interlayer insulating layer 113, a first planarization layer 114, a second planarization layer 115, a third planarization layer 116, a fourth planarization layer 117, a transistor DT, a first light emitting diode LED1, a first bonding layer BL1, a first reflection electrode RE1, a second reflection electrode RE2, a plurality of reflection layers RL, a power line VL, a connection electrode CE, and a black bank BB.

First, the substrate 110 is a component for supporting various components included in the display device 100 and may be formed of an insulating material. For example, the substrate 110 may be formed of glass or resin. Further, the substrate 110 may be configured to include a polymer or plastics or may be formed of a material having flexibility.

A light shielding layer LS may be disposed on the substrate 110. The light shielding layer LS blocks light from below the substrate 110 from being incident onto an active layer ACT of the driving transistor DT to be described below. Light from below the substrate 110 is blocked by the light shielding layer LS from being incident onto the active layer ACT of the driving transistor DT to minimize a leakage current.

Further, the power line VL may be disposed on the substrate 110. Specifically, the power line VL may be disposed to be spaced apart from the light shielding layer LS on the same layer as the light shielding layer LS. Further, the power line VL is formed of the same material as the light shielding layer LS, but the present disclosure is not limited thereto. The power line VL may be a low potential power line and in this case, a low potential voltage is supplied to the power line VL. However, the present disclosure is not limited thereto and the power line VL may be a high potential power line.

The buffer layer 111 may be disposed on the power line VL and the light shielding layer LS. The buffer layer 111 may reduce permeation of moisture or impurities through the substrate 110. For example, the buffer layer 111 may be configured by a single layer or a double layer of silicon oxide (SiOx) or silicon nitride (SiNx), but the present disclosure is not limited thereto. However, the buffer layer 111 may be omitted depending on a type of substrate 110 or a type of transistor, but the present disclosure is not limited thereto. The buffer layer 111 may include a contact hole to be described below through which the first reflection electrode RE1 and the power line VL are connected.

The driving transistor DT is disposed on the buffer layer 111. The driving transistor DT may include an active layer ACT, a gate electrode GE, a source electrode SE, and a drain electrode DE.

The active layer ACT may be disposed on the buffer layer 111. The active layer ACT may be formed of a semiconductor material, such as an oxide semiconductor, amorphous silicon, or polysilicon, but the present disclosure is not limited thereto.

The gate insulating layer 112 may be disposed on the active layer ACT. The gate insulating layer 112 is an insulating layer for insulating the active layer ACT from the gate electrode GE. Therefore, the gate insulating layer 112 may be disposed only between the gate electrode GE and the active layer ACT, but the present disclosure is not limited thereto. For example, a maximum width of the gate insulating layer 112 may be smaller than a maximum width of the active layer ACT. Further, the gate insulating layer 112 may completely overlap the active layer ACT. Further, the gate insulating layer 112 may be spaced apart from the source electrode SE and the drain electrode DE to be described below. For example, the gate insulating layer 112 may be configured by a single layer or a double layer of silicon oxide (SiOx) or silicon nitride (SiNx), but the present disclosure is not limited thereto.

The gate electrode GE may be disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but the present disclosure is not limited thereto.

The interlayer insulating layer 113 may be disposed on the gate insulating layer 112. The interlayer insulating layer 113 may include a contact hole for connecting the source electrode SE and the active layer ACT. The interlayer insulating layer 113 is an insulating layer which protects components below the interlayer insulating layer 113 and may be configured by a single layer or a double layer of silicon oxide (SiOx) or silicon nitride (SiNx), but the present disclosure is not limited thereto.

The source electrode SE and the drain electrode DE which are electrically connected to the active layer ACT may be disposed on the interlayer insulating layer 113. The source electrode SE and the drain electrode DE may be disposed on the same layer to be spaced apart from each other. The source electrode SE is connected to the active layer ACT through a contact hole included in the interlayer insulating layer 113. The drain electrode DE may be connected to the active layer ACT through a contact hole included in the interlayer insulating layer 113. The source electrode SE and the drain electrode DE may be configured by a conductive material, such as copper (Cu), aluminum (Al), molybdenum (Mo), nickel (Ni), titanium (Ti), chrome (Cr), or an alloy thereof, but the present disclosure is not limited thereto.

The first planarization layer 114 may be disposed on the source electrode SE and the drain electrode DE. The first planarization layer 114 may planarize an upper portion of the pixel circuit including the driving transistor DT. The first planarization layer 114 may be configured by a single layer or a double layer, and for example, configured by benzocyclobutene or an acrylic-based organic material, but the present disclosure is not limited thereto.

The first bonding layer BL1 is disposed on the first planarization layer 114. The first bonding layer BL1 serves to fix the first light emitting diode LED1 to be described below. Therefore, the first bonding layer BL1 is disposed in a position corresponding to the first light emitting diode LED1. At this time, a maximum width of the first bonding layer BL1 may be larger than a maximum width of the first light emitting diode LED1. The first light emitting diode LED1 may be disposed inside the first bonding layer BL1 and disposed on the first bonding layer BL1. Specifically, the first light emitting diode LED1 is disposed on the first bonding layer BL1 so as not to be deviated from the first bonding layer BL1.

A part of a top surface of the first bonding layer BL1 is in contact with a bottom surface of the first electrode E1 of the first light emitting diode LED1 and the first bonding layer BL1 may be disposed so as to enclose the side surface of the first electrode E1 of the first light emitting diode LED1. For example, the first bonding layer BL1 may be disposed so as to enclose the entire side surface of the first electrode E1. Specifically, the first bonding layer BL1 may include a concave portion on the top surface and the first electrode E1 is inserted into the concave portion of the first bonding layer BL1. Further, the first bonding layer BL1 may be in contact with a part of the bottom surface of the first semiconductor layer L1 of the first light emitting diode LED1, but the present disclosure is not limited thereto.

The first bonding layer BL1 includes a conductive black material. Therefore, the first bonding layer BL1 may be black. For example, the conductive black material may include carbon. For example, the first bonding layer BL1 may be formed by dispersing a conductive black material including carbon in an acrylic resin, but the present disclosure is not limited thereto. As described above, the first bonding layer BL1 includes a conductive black material to electrically connect the first reflection electrode RE1 to be described below and the first electrode E1.

The first reflection electrode RE1 and the second reflection electrode RE2 are disposed on the first planarization layer 114. Therefore, the first reflection electrode RE1 and the second reflection electrode RE2 may be disposed on the same layer as the first bonding layer BL1. At this time, a thickness of the first reflection electrode RE1 and the second reflection electrode RE2 is smaller than a thickness of the first bonding layer BL1. Therefore, top surfaces of the first reflection electrode RE1 and the second reflection electrode RE2 may be disposed to be lower than a top surface of the first bonding layer BL1.

The first reflection electrode RE1 is in contact with a side surface of the first bonding layer BL1. Specifically, the first reflection electrode RE1 may be disposed so as to enclose a side surface of the first bonding layer BL1. Therefore, the first reflection electrode RE1 may be electrically connected to the first bonding layer BL1. The first reflection electrode RE1 may be electrically connected to the power line VL through contact holes of the first planarization layer 114, the interlayer insulating layer 113, and the buffer layer 111. Therefore, the first reflection electrode RE1 may electrically connect the power line VL and the first bonding layer BL1.

The second reflection electrode RE2 may be spaced apart from the first reflection electrode RE1. The second reflection electrode RE2 may be connected to the drain electrode DE of the driving transistor DT through a contact hole of the first planarization layer 114. Further, the second reflection electrode RE2 may be electrically connected to the second electrode E2 of the first light emitting diode LED1 through the connection electrode CE to be described below.

The first reflection electrode RE1 and the second reflection electrode RE2 may include various conductive layers by considering a light reflection efficiency and resistance. For example, the first reflection electrode RE1 and the second reflection electrode RE2 may use an opaque conductive layer, such as silver (Ag), aluminum (Al), molybdenum (Mo), titanium (Ti), or an alloy thereof, and a transparent conductive layer, such as indium tin oxide (ITO) together, but the present disclosure is not limited thereto.

The first light emitting diode LED1 is disposed on the first bonding layer BL1. The first light emitting diode LED1 includes a first electrode E1, a first semiconductor layer L1, an active layer EL, a second semiconductor layer L2, and a second electrode E2.

The first electrode E1 may be a cathode electrode for injecting electrons to the active layer EL. Further, the first electrode E1 is a cathode electrode and also serves as a reflection layer which reflects upwardly light emitted from the active layer EL. The first electrode E1 may be configured by a conductive material, for example, a transparent conductive material, such as indium tin oxide (ITO) or indium zinc oxide (IZO) or a reflective conductive material, such as titanium (Ti), gold (Au), silver (Ag), copper (Cu) or an alloy thereof, but the present disclosure is not limited thereto.

The first semiconductor layer L1 is disposed on the first electrode E1. The first semiconductor layer may be a layer doped with an n-type impurity. For example, the first semiconductor layer L1 may be a layer formed by doping an n-type impurity into a material such as gallium nitride (GaN), indium aluminum phosphide (InAlP), or gallium arsenide (GaAs). The n-type impurity may be silicon (Si), germanium, or tin (Sn), but the present disclosure is not limited thereto.

A width of the bottom surface of the first semiconductor layer L1 may be larger than a width of the top surface of the first electrode E1. Therefore, at least a part of the bottom surface of the first semiconductor layer L1 may be exposed by the first electrode E1. A part of the bottom surface of the first semiconductor layer L1 exposed as described above may be bonded to the first bonding layer BL1.

Alternatively, the width of the bottom surface of the first semiconductor layer L1 may be equal to the width of the top surface of the first electrode E1. In this case, the bottom surface of the first semiconductor layer L1 is not in contact with the first bonding layer BL1. Therefore, the bottom surface and the side surface of the first electrode E1 are bonded to the first bonding layer BL1 to fix the first light emitting diode LED1.

The active layer EL is disposed on the first semiconductor layer L1. The active layer EL is supplied with holes and electrons from the first semiconductor layer L1 and the second semiconductor layer L2 to emit light. The active layer EL may be formed by a single layer or a multi-quantum well (MQW) structure, and for example, may be formed of indium gallium nitride (InGaN), gallium arsenide (GaAs), or gallium nitride (GaN), but the present disclosure is not limited thereto.

The second semiconductor layer L2 is disposed on the active layer EL. The second semiconductor layer L2 may be a layer formed by doping a p-type impurity into a specific material. For example, the second semiconductor layer L2 may be a layer formed by doping a p-type impurity into a material such as gallium nitride (GaN), indium aluminum phosphide (InAlP), or gallium arsenide (GaAs). At this time, the p-type impurity may be magnesium, zinc (Zn), or beryllium (Be), but the present disclosure is not limited thereto.

The second electrode E2 is disposed on the second semiconductor layer L2. The second electrode E2 may be an anode electrode for injecting holes to the active layer EL. The second electrode E2 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but the present disclosure is not limited thereto.

A maximum width of the second electrode E2 may be smaller than a width of the top surface of the second semiconductor layer L2. Therefore, at least a part of the top surface of the second semiconductor layer L2 may be exposed by the second electrode E2.

Next, the encapsulation film PAS which encloses the first semiconductor layer L1, the active layer EL, the second semiconductor layer L2, and the second electrode E2 may be disposed.

The encapsulation film PAS is formed of an insulating material to protect the first semiconductor layer L1, the active layer EL, and the second semiconductor layer L2. In the encapsulation film PAS, a contact hole which exposes the second electrode E2 is formed to electrically connect the connection electrode CE to be described below and the second electrode E2.

In the meantime, a part of the side surface of the first semiconductor layer L1 may be exposed from the encapsulation film PAS. The first light emitting diode LED1 manufactured on a wafer is separated from the wafer to be transferred onto the display panel PN. However, during the process of separating the first light emitting diode LED1 from the wafer, a part of the encapsulation film PAS may be torn. For example, a part of the encapsulation film PAS6 which is adjacent to a lower edge of the first semiconductor layer L1 of the first light emitting diode LED1 is torn during the process of separating the first light emitting diode LED1 from the wafer. Accordingly, a lower portion of the side surface of the first semiconductor layer L1 may be exposed to the outside. However, although the lower portion of the first light emitting diode LED1 is exposed from the encapsulation film PAS, the connection electrode CE is formed after forming the first planarization layer 115 and the second planarization layer 116 which cover the side surface of the first semiconductor layer L1. Accordingly, a short-circuit defect may be reduced. The plurality of reflection layers RL is disposed on the first reflection electrode RE1 and the first bonding layer BL1. The plurality of reflection layers RL serves to reflect upwardly light emitted from the first light emitting diode LED1 and serves as an electrode which electrically connects the power line VL and the first light emitting diode LED1. The plurality of reflection layers RL is electrically connected to the first reflection electrode RE1. For example, the plurality of reflection layers RL is in contact with the top surface of the first reflection electrode RE1. At this time, one of end portions of the plurality of reflection layers RL may be disposed on the top surface of the first reflection electrode RE1. For example, one of end portions of the plurality of reflection layers RL may be disposed inside the end portion of the first reflection electrode RE1.

The plurality of reflection layers RL may be continued from the top surface of the first reflection electrode RE1 to the top surface of the first bonding layer BL1. Therefore, the plurality of reflection layers RL may be disposed so as to cover the side surface of the first bonding layer BL1. Specifically, the plurality of reflection layers RL may cover fully a part of the side surface of the first bonding layer BL1 which is not in contact with the first reflection electrode RE1. Further, the plurality of reflection layers RL may cover at least a part of the top surface of the first bonding layer BL1. Specifically, the reflection layer RL may cover fully a part of the top surface of the first bonding layer BL1 which is not in contact with the first light emitting diode LED1. Therefore, the reflection layer RL may be electrically connected to the first reflection electrode RE1 and the first bonding layer BL1.

Further, the reflection layer RL extends to the top surface of the first bonding layer BL1 and may be continued to at least a part of the side surface of the first semiconductor layer L1 of the first light emitting diode LED1. Therefore, the reflection layer RL may be in contact with at least a part of the side surface of the first semiconductor layer L1 exposed from the encapsulation film PAS. At this time, a maximum height of the reflection layer RL may be lower than the active layer EL. As described above, the reflection layer RL may electrically connect the power line VL and the first light emitting diode LED1. The reflection layer RL may be disposed so as to enclose the side surface of the first semiconductor layer L1.

The reflection layer RL may be a high reflective metal material, such as silver (Ag), aluminum (Al), molybdenum (Mo), or titanium (Ti), but the present disclosure is not limited thereto.

The second planarization layer 115 may be disposed on the reflection layer RL. The second planarization layer 115 may planarize upper portions of the first reflection electrode RE1, the second reflection electrode RE2, the first bonding layer BL1, and the reflection layer RL disposed therebelow. Therefore, the second planarization layer 115 may cover at least a part of the first reflection electrode RE1, the second reflection electrode RE2, and the reflection layer RL.

A height of the top surface of the second planarization layer 115 may be equal to a height of an uppermost edge of the reflection layer RL. Therefore, the top surface of the reflection layer RL may be exposed by the second planarization layer 115. Further, the second planarization layer 115 may include a contact hole CH which connects the connection electrode CE to be described below and the second reflection electrode RE2.

The third planarization layer 116 may be disposed on the second planarization layer 115. The third planarization layer 116 may be in contact with at least a part of the side surface of the first light emitting diode LED1. Further, the third planarization layer 116 may be disposed so as to enclose the first light emitting diode LED1. Therefore, the third planarization layer 116 may fix and protect the first light emitting diode LED1.

The third planarization layer 116 may cover the uppermost edge of the plurality of reflection layers RL exposed by the second planarization layer 115. Further, the third planarization layer 116 may include a contact hole CH which connects the connection electrode CE to be described below and the second reflection electrode RE2. At this time, the contact hole CH of the third planarization layer 116 is connected to the contact hole of the second planarization layer 115 to form one contact hole CH.

The second planarization layer 115 and the third planarization layer 116 may be configured by benzocyclobutene or an acrylic-based organic material, but the present disclosure is not limited thereto. The second planarization layer 115 and the third planarization layer 116 may be formed of different materials, but the present disclosure is not limited thereto.

The connection electrode CE may be disposed on the third planarization layer 116. The connection electrode CE may be connected to the second reflection electrodes RE2 through contact holes CH of the second planarization layer 115 and the third planarization layer 116. Further, the connection electrode CE may be connected to the second electrode E2 exposed by the encapsulation film PAS. Therefore, the connection electrode CE may electrically connect the drain electrode DE of the driving transistor DT and the second electrode E2 of the first light emitting diode LED1.

The connection electrode CE may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but the present disclosure is not limited thereto.

The black bank BB may be disposed on the third planarization layer 116 and the connection electrode CE. The black bank BB is a component for distinguishing adjacent sub pixels SP. The black bank BB may be disposed so as not to overlap the active layer EL of the first light emitting diode LED1. The black bank BB may cover one end portion of the connection electrode CE. Therefore, the black bank BB may cover at least a part of the top surface of the connection electrode CE. Further, the black bank BB may be filled in the contact hole of the connection electrode CE.

The black bank BB may be formed of acrylic-based resin, benzocyclobutene (BCB)-based resin, or polyimide and further include a black component, but the present disclosure is not limited thereto.

The fourth planarization layer 117 may be disposed on the black bank BB. The fourth planarization layer 117 covers the third planarization layer 116, the connection electrode CE, and the black bank BB to protect configurations disposed therebelow. The fourth planarization layer 117 may be configured by a single layer or a double layer, and for example, may be formed of a photo resist or an acrylic-based organic material, but the present disclosure is not limited thereto.

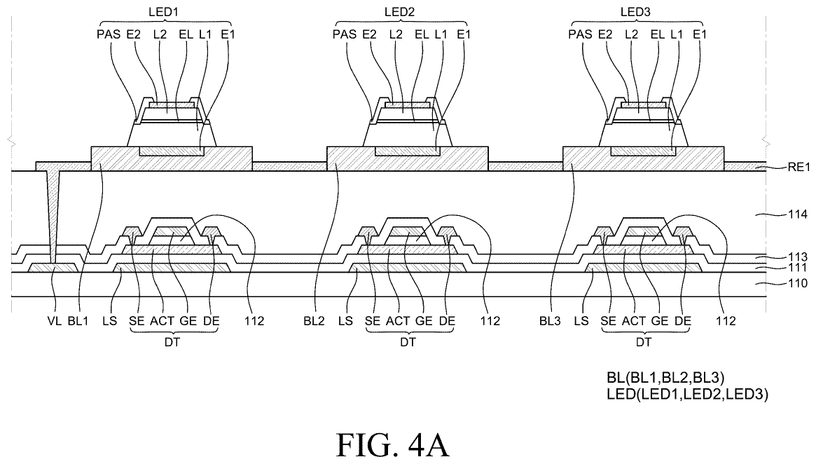

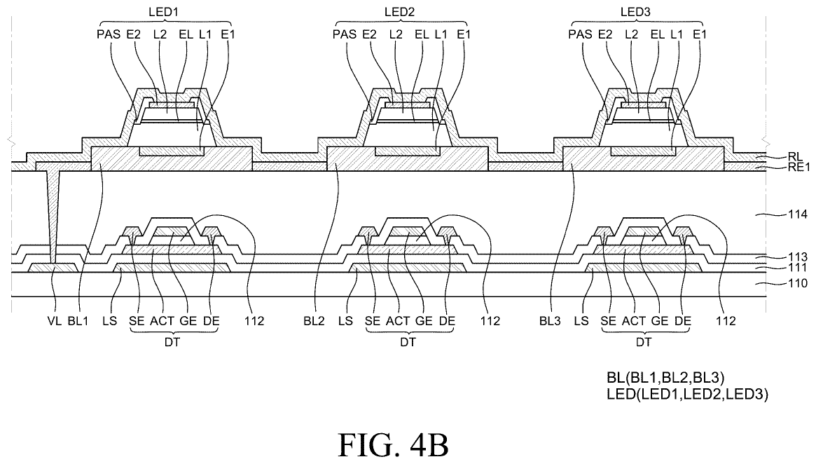

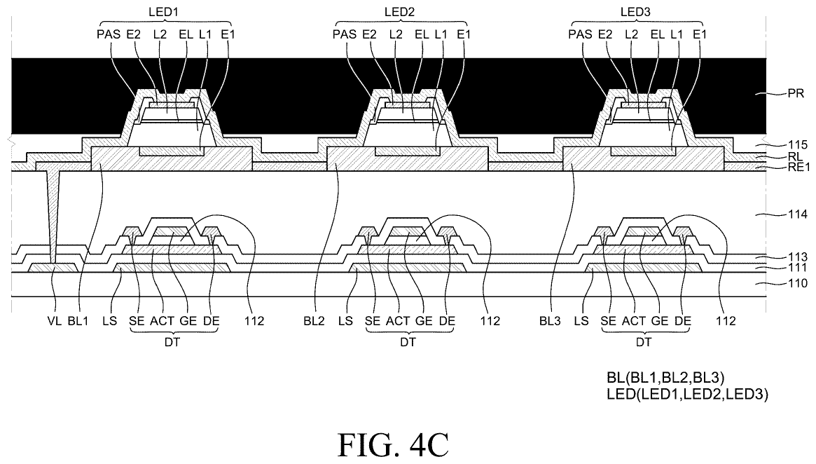

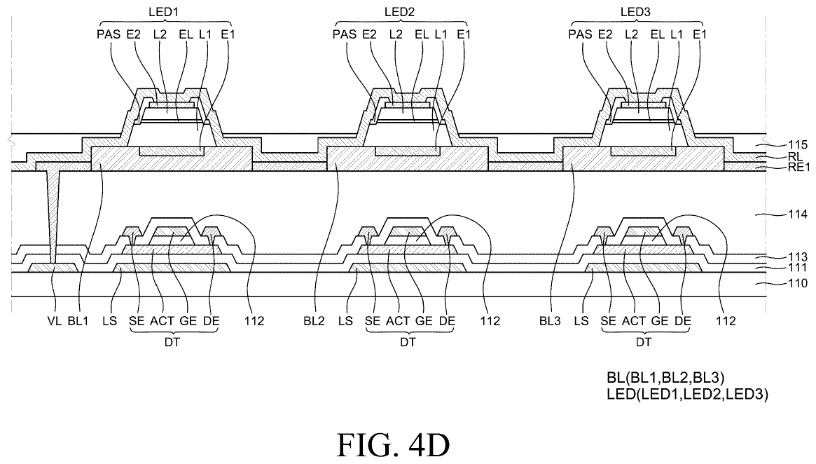

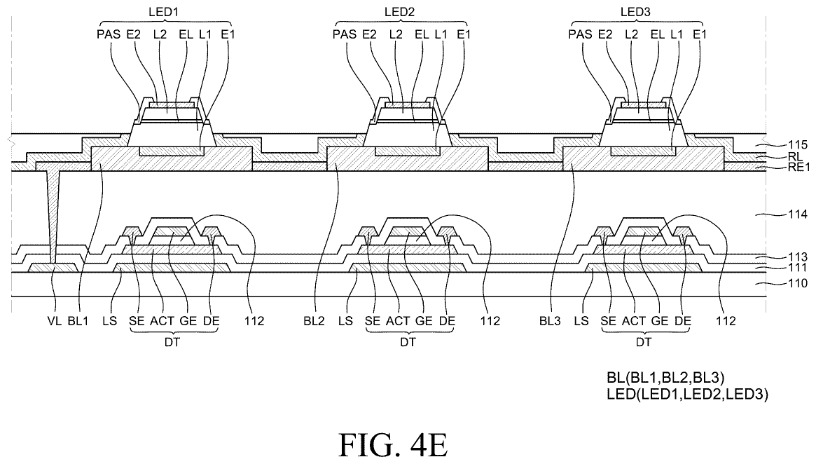

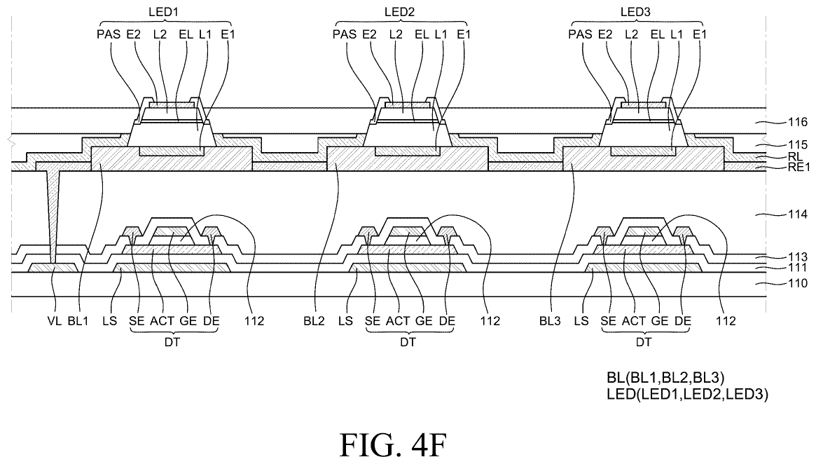

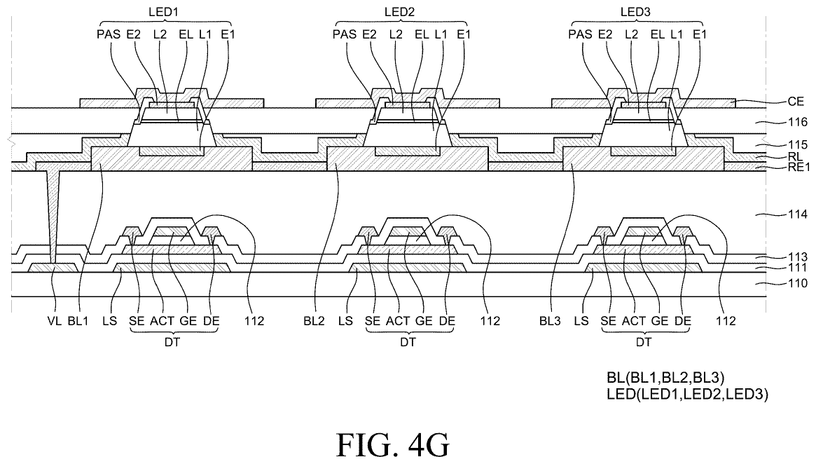

Hereinafter, a manufacturing method of a display device 100 according to an example embodiment of the present disclosure will be described in detail with reference to FIGS. 4A to 4G.

FIGS. 4A to 4G are process diagrams for explaining a manufacturing method of a pixel of a display device according to an example embodiment of the present disclosure.

First, referring to FIG. 4A, the first reflection electrode RE1 may be disposed on the substrate 110. Next, after forming a plurality of holes which exposes the first planarization layer 114 by patterning and etching the first reflection electrode RE1, the plurality of bonding layers BL may be formed on the exposed first planarization layer 114. Therefore, the plurality of bonding layers BL may be formed on the substrate 110. The plurality of light emitting diodes LED may be transferred onto the plurality of formed bonding layers BL. At this time, the first electrode E1 of each of the plurality of light emitting diodes LED is inserted into the bonding layer BL to be bonded. Further, each of the plurality of bonding layers BL may be formed to be wider than each of the plurality of light emitting diodes LED. Therefore, even though an alignment error occurs during the process of transferring the plurality of light emitting diodes LED, the plurality of light emitting diodes LED may be stably transferred onto the plurality of bonding layers BL.

Next, referring to FIG. 4B, the plurality of reflection layers RL may be formed by applying a material for forming the plurality of reflection layers RL on the first reflection electrode RE1, the plurality of bonding layers BL, and the plurality of light emitting diodes LED. At this time, the plurality of reflection layers RL may be formed to cover entirely the first reflection electrode RE1, the plurality of bonding layers BL, and the plurality of light emitting diodes LED. Therefore, the plurality of reflection layers RL may be connected to the first reflection electrode RE1 and the plurality of bonding layers BL.

Next, referring to FIG. 4C, a photo resist PR for removing the plurality of reflection layers RL from an area other than a peripheral portion adjacent to the plurality of light emitting diodes LED may be applied. Next, a patterning process for removing the plurality of reflection layers RL may be performed on an area which is not covered by the photo resist PR. The plurality of reflection layers RL may be formed only in the peripheral portion adjacent to the plurality of light emitting diodes LED through the process as described above.

Next, referring to FIG. 4D, the photo resist PR is removed and a material for forming the second planarization layer 115 may be applied. Further, an etching process of the second planarization layer 115 is performed to expose a part of the plurality of reflection layers RL. At this time, a maximum height of the second planarization layer 115 may be formed to be lower than the active layer EL of each of the plurality of light emitting diodes LED. As described above, the plurality of reflection layers RL is formed first, the second planarization layer 115 is formed, and then the second planarization layer 115 is etched so that the second planarization layer 115 encloses the side surfaces of the plurality of light emitting diodes LED, but is not in contact with the side surfaces of the plurality of light emitting diodes LED.

Next, referring to FIG. 4E, a process of removing the plurality of reflection layers RL exposed by etching the second planarization layer 115 may be performed. By doing this, a plurality of reflection layers RL exposed by the second planarization layer 115 is fully removed and only a plurality of reflection layers RL covered by the second planarization layer 115 may be maintained. Further, top surfaces of the plurality of reflection layers RL may be exposed at the same height as the maximum height of the second planarization layer 115.

Next, referring to FIG. 4F, a material for forming the third planarization layer 116 may be applied on the second planarization layer 115. Further, after applying the material for forming the third planarization layer 116, an etching process for exposing the top surfaces of the plurality of light emitting diodes LED may be performed. Specifically, the second electrode E2 of each of the plurality of light emitting diodes LED may be exposed by means of the etching process of the third planarization layer 116.

Next, referring to FIG. 4G, a material for forming the connection electrode CE is applied and patterned on the second electrode E2 exposed from the third planarization layer 116 to form the connection electrode CE. Specifically, a process of patterning the connection electrode CE may be performed to place the connection electrode CE on each of the second electrodes E2 of the plurality of light emitting diodes LED. For example, the connection electrode CE may be disposed on each of the first light emitting diodes LED1, the second light emitting diodes LED2, and the third light emitting diodes LED3. Further, the connection electrodes CE disposed on the first light emitting diodes LED1, the second light emitting diodes LED2, and the third light emitting diodes LED3 are patterned to be spaced apart from each other.

In the meantime, the light emitting diode LED is a semiconductor light emitting diode which converts current into light and is used to implement various display devices. In order to implement a high resolution in the display device, more pixels need to be disposed in a limited space. Therefore, the size of the pixel needs to be smaller and the light emitting diode disposed in the sub pixel in the pixel also needs to be small-sized. As described above, the light emitting diode with a reduced size is transferred and fixed onto the substrate using an adhesive layer including conductive balls.

However, even though the size of the light emitting diode becomes smaller, there is a limitation in reducing the size of the conductive balls included in the adhesive layer. Therefore, even though the size of the light emitting diode is reduced, there is a problem in that the size of the adhesive layer including conductive balls is not reduced. Accordingly, since the size of the adhesive layer including the conductive balls is larger than the small-sized light emitting diode, as a result, there is a problem in that the size of the overall pixel may not be reduced.

Therefore, the display device 100 according to the example embodiment of the present disclosure includes a plurality of bonding layers BL including a conductive black material. Further, the plurality of bonding layers BL is patterned so as to correspond to the plurality of light emitting diodes LED, respectively. As described above, in the display device 100 according to the example embodiment of the present disclosure, the plurality of bonding layers BL does not include conductive balls, so that the size of each of the plurality of bonding layers may be reduced more. Therefore, the entire size of the pixel PX including the plurality of bonding layers BL may be reduced. Further, as described above, the size of the pixel PX is reduced so that more pixels PX may be disposed in the same area so that the display device 100 with a high resolution may be implemented.

Further, in the display device 100 according to the example embodiment of the present disclosure, the plurality of bonding layers BL may be disposed to be larger than the plurality of light emitting diodes LED. Therefore, in the display device 100 according to the example embodiment of the present disclosure, even though the alignment error occurs during the process of transferring the plurality of light emitting diodes LED, the plurality of light emitting diodes LED may be stably bonded onto the plurality of bonding layers BL.

Further, the display device 100 according to the example embodiment of the present disclosure includes a plurality of reflection layers RL disposed on the plurality of bonding layers BL. Therefore, light emitted from the plurality of light emitting diodes LED may be suppressed from being absorbed by the plurality of bonding layers BL which is black, in the vicinity of the plurality of light emitting diode LED. Therefore, a luminous efficiency of the plurality of light emitting diode LED may be improved.

Further, in the display device 100 according to the example embodiment of the present disclosure, light emitted from the plurality of light emitting diodes LED is upwardly reflected by the plurality of reflection layers RL so that the light extraction efficiency of the display device 100 may be improved. As described above, as the light extraction efficiency of the display device 100 is improved, the display device 100 with a high resolution may be driven even with a low power.

Further, in the display device 100 according to the example embodiment of the present disclosure, a width of the first electrode E1 of the plurality of light emitting diodes LED may be disposed to be equal to a width of the bottom surface of the first semiconductor layer L1. By doing this, light emitted from the active layer EL of the plurality of light emitting diodes LED may be suppressed from passing through the first semiconductor layer L1 to be absorbed by the plurality of bonding layers BL in an area overlapping the plurality of light emitting diodes LED. Further, the light emitted from the active layer EL is reflected to the upper portion of the plurality of light emitting diodes LED by the first electrode E1 so that the luminous efficiency may be further improved.

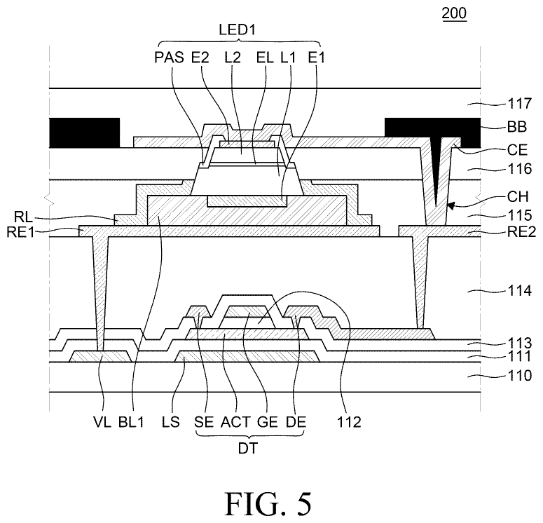

FIG. 5 is a cross-sectional view of a sub pixel of a display device according to another example embodiment of the present disclosure. A sub pixel SP of a display device 200 of FIG. 5 has substantially same components as the sub pixel SP of FIG. 3 except that the first reflection electrode RE1 is disposed below the plurality of bonding layers BL. Therefore, a redundant description will be omitted.

Referring to FIG. 5, the first reflection electrode RE1 may be disposed below the first bonding layers BL1. For example, the first bonding layer BL1 may be disposed between the first reflection electrode RE1 and the first light emitting diode LED1. A width of the first reflection electrode RE1 may be larger than a width of the first bonding layer BL1. Further, the first reflection electrode RE1 may completely overlap the first bonding layer BL1. For example, the first bonding layer BL1 may be disposed on the first reflection electrode RE1 so as not to be deviated from the first reflection electrode RE1. The top surface of the first reflection electrode RE1 may be in contact with the bottom surface of the first bonding layer BL1. Therefore, the first reflection electrode RE1 and the first bonding layer BL1 may be electrically connected to each other.

An end of the first reflection electrode RE1 may be disposed outside ends of the plurality of reflection layers RL disposed on the first reflection electrode RE1. Therefore, all the ends of the plurality of reflection layers RL may be disposed to be in contact with the top surface of the first reflection electrode RE1, but the present disclosure is not limited thereto. Therefore, the plurality of reflection layers RL and the first reflection electrode RE1 may be electrically connected to each other.

In the display device 200 according to another example embodiment of the present disclosure, the plurality of bonding layers BL does not include conductive balls, so that the size of each of the plurality of bonding layers may be reduced more. Therefore, the entire size of the pixel PX including the plurality of bonding layers BL may be reduced. Further, as described above, the size of the pixel PX is reduced so that more pixels PX may be disposed in the same area so that the display device 200 with a high resolution may be implemented.

Further, in the display device 200 according to another example embodiment of the present disclosure, even though the alignment error occurs during the process of transferring the plurality of light emitting diodes LED, the plurality of light emitting diodes LED may be stably bonded onto the plurality of bonding layers BL.

Further, the display device 200 according to another example embodiment of the present disclosure includes a plurality of reflection layers RL disposed on the plurality of bonding layers BL. Therefore, light emitted from the plurality of light emitting diodes LED may be suppressed from being absorbed by the plurality of bonding layers BL which is black, in the vicinity of the plurality of light emitting diode LED. Therefore, a luminous efficiency of the plurality of light emitting diode LED may be improved.

Further, in the display device 200 according to another example embodiment of the present disclosure, light emitted from the plurality of light emitting diodes LED is upwardly reflected by the plurality of reflection layers RL so that the light extraction efficiency of the display device 200 may be improved.

Further, in the display device 200 according to another example embodiment of the present disclosure, the first reflection electrode RE1 may be disposed below the plurality of bonding layers BL. Therefore, when a part of light emitted from the plurality of light emitting diodes LED passes through the plurality of bonding layers BL in an area overlapping the plurality of light emitting diodes LED, the light is upwardly reflected by the first reflection electrode RE1. Accordingly, the light extraction efficiency of the display device 200 may be improved.

The example embodiments of the present disclosure can also be described as follows:

A display device according to an aspect of the present disclosure comprises a substrate, a plurality of sub pixels, a plurality of transistors disposed on the substrate, a plurality of reflection electrodes disposed on the plurality of transistors, a plurality of bonding layers which is bonded to some of the plurality of reflection electrodes and includes a conductive black material, a plurality of light emitting diodes which is disposed on the plurality of bonding layers so as to correspond to the plurality of bonding layers and includes a first electrode, a first semiconductor layer, an active layer, a second semiconductor layer, and a second electrode, and a plurality of reflection layers which is disposed on the plurality of bonding layers, is electrically connected to the plurality of reflection electrodes, respectively, and is in contact with the plurality of light emitting diodes.

A width of each of the plurality of bonding layers may be larger than a maximum width of each of the plurality of light emitting diodes.

Each of the plurality of bonding layers may enclose a side surface of the first electrode.

The plurality of reflection layers may be disposed so as to cover a part of top surfaces of the plurality of bonding layers above which the plurality of light emitting diodes may not be disposed.

The plurality of reflection layers may be disposed so as to cover side surfaces of the plurality of bonding layers.

A width of a top surface of the first electrode may be equal to a width of a bottom surface of the first semiconductor layer.

The plurality of reflection layers may be in contact with at least a part of a side surface of the first semiconductor layer.

The plurality of reflection electrodes may include a plurality of first reflection electrodes which is electrically connected to the plurality of bonding layers, and a plurality of second reflection electrodes which is disposed to be spaced apart from the plurality of first reflection electrodes, wherein the plurality of reflection layers may be electrically connected to the plurality of first reflection electrodes.

The plurality of bonding layers may be disposed on a same layer as the plurality of first reflection electrodes and the plurality of second reflection electrodes.

The plurality of bonding layers may be disposed between the plurality of first reflection electrodes and the plurality of light emitting diodes.

The display device according to an aspect of the present disclosure may further comprise a power line disposed on the substrate, wherein the plurality of first reflection electrodes is electrically connected to the power line.

The plurality of light emitting diodes may completely overlap the plurality of bonding layers, respectively.

A display device according to another aspect of the present disclosure comprise a substrate, a transistor disposed on the substrate, a power line disposed on the substrate, a first reflection electrode which is disposed on the transistor and is electrically connected to the transistor, a second reflection electrode which is disposed on the power line and is electrically connected to the power line, a bonding layer which is electrically connected to one of the first reflection electrode and the second reflection electrode and includes a conductive black material, a light emitting diode disposed on the bonding layer, and a reflection layer which is disposed so as to cover the bonding layer.

The one of the first reflection electrode and the second reflection electrode may be in contact with a side surface of the bonding layer and may be disposed so as to enclose the side surface of the bonding layer.

The one of the first reflection electrode and the second reflection electrode, the bonding layer, and the light emitting diode may be sequentially laminated.

The reflection layer may electrically connect the one of the first reflection electrode and the second reflection electrode and the light emitting diode.

The display device according to another aspect of the present application may further comprise a connection electrode which electrically connects the other one of the first reflection electrode and the second reflection electrode and the light emitting diode.

The reflection layer may be in contact with a side surface of the light emitting diode.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a plurality of sub pixels;
a plurality of transistors disposed on the substrate;
a plurality of reflection electrodes disposed on the plurality of transistors;
a plurality of bonding layers which is bonded to some of the plurality of reflection electrodes and includes a conductive black material;
a plurality of light emitting diodes which is disposed on the plurality of bonding layers so as to correspond to the plurality of bonding layers and includes a first electrode, a first semiconductor layer, an active layer, a second semiconductor layer, and a second electrode; and
a plurality of reflection layers which is disposed on the plurality of bonding layers, is electrically connected to the plurality of reflection electrodes, respectively, and is in contact with the plurality of light emitting diodes.

2. The display device according to claim 1, wherein a width of each of the plurality of bonding layers is larger than a maximum width of each of the plurality of light emitting diodes.

3. The display device according to claim 1, wherein each of the plurality of bonding layers encloses a side surface of the first electrode.

4. The display device according to claim 1, wherein the plurality of reflection layers is disposed so as to cover a part of top surfaces of the plurality of bonding layers above which the plurality of light emitting diodes is not disposed.

5. The display device according to claim 1, wherein the plurality of reflection layers is disposed so as to cover side surfaces of the plurality of bonding layers.

6. The display device according to claim 1, wherein a width of a top surface of the first electrode is equal to a width of a bottom surface of the first semiconductor layer.

7. The display device according to claim 1, wherein the plurality of reflection layers is in contact with at least a part of a side surface of the first semiconductor layer.

8. The display device according to claim 1, wherein the plurality of reflection electrodes includes:
a plurality of first reflection electrodes which is electrically connected to the plurality of bonding layers; and
a plurality of second reflection electrodes which is disposed to be spaced apart from the plurality of first reflection electrodes,
wherein the plurality of reflection layers is electrically connected to the plurality of first reflection electrodes.

9. The display device according to claim 8, wherein the plurality of bonding layers is disposed on a same layer as the plurality of first reflection electrodes and the plurality of second reflection electrodes.

10. The display device according to claim 8, wherein the plurality of bonding layers is disposed between the plurality of first reflection electrodes and the plurality of light emitting diodes.

11. The display device according to claim 8, further comprising:
a power line disposed on the substrate,
wherein the plurality of first reflection electrodes is electrically connected to the power line.

12. The display device according to claim 1, wherein the plurality of light emitting diodes completely overlaps the plurality of bonding layers, respectively.

13. A display device, comprising:
a substrate;
a transistor disposed on the substrate;
a power line disposed on the substrate;
a first reflection electrode which is disposed on the transistor and is electrically connected to the transistor;
a second reflection electrode which is disposed on the power line and is electrically connected to the power line;
a bonding layer which is electrically connected to one of the first reflection electrode and the second reflection electrode and includes a conductive black material;
a light emitting diode disposed on the bonding layer; and
a reflection layer which is disposed so as to cover the bonding layer.

14. The display device according to claim 13, wherein the one of the first reflection electrode and the second reflection electrode is in contact with a side surface of the bonding layer and is disposed so as to enclose the side surface of the bonding layer.

15. The display device according to claim 13, wherein the one of the first reflection electrode and the second reflection electrode, the bonding layer, and the light emitting diode are sequentially laminated.

16. The display device according to claim 13, wherein the reflection layer electrically connects the one of the first reflection electrode and the second reflection electrode and the light emitting diode.

17. The display device according to claim 13, further comprising:
a connection electrode which electrically connects the other one of the first reflection electrode and the second reflection electrode and the light emitting diode.

18. The display device according to claim 13, wherein the reflection layer is in contact with a side surface of the light emitting diode.
